(19) United States
(12) Patent Application Publication
(10) Pub. No.: US 2026/0101454 A1
(43) Pub. Date: Apr. 9, 2026

(54) ANGLE ADJUSTING DEVICE FOR DISPLAY

(71) Applicant: SAMSUNG ELECTRONICS CO., LTD., Suwon-si (KR)

(72) Inventors: Jinho KIM, Suwon-si (KR); Daesoo KIM, Suwon-si (KR); Heeseung CHOI, Suwon-si (KR); Cheoggyu HWANG, Suwon-si (KR)

(73) Assignee: SAMSUNG ELECTRONICS CO., LTD., Suwon-si (KR)

(21) Appl. No.: 19/416,674

(22) Filed: Dec. 11, 2025

Related U.S. Application Data
(63) Continuation of application No. PCT/KR2024/006735, filed on May 17, 2024.

(30) Foreign Application Priority Data
Jul. 14, 2023 (KR) 10-2023-0091991

(51) Int. Cl. H05K 5/02; F16M 11/12; F16M 11/18

(52) U.S. Cl. CPC H05K 5/0217; F16M 11/125; F16M 11/18

(57) ABSTRACT

An angle adjusting device for a display includes a base, a joint disposed between the base and the display. The joint changes an angle of the display. The device includes a first driving motor providing power to one side of the joint, and a second driving motor providing power to the other side of the joint. The joint includes a connecting core, and a first rotating member, a second rotating member, a third rotating member and a fourth rotating member rotatably connected to the connecting core respectively in four directions of the connecting core. The first rotating member and the second rotating member are disposed along a first axis, and the third rotating member and the fourth rotating member are disposed along a second axis perpendicular to the first axis. The third rotating member is rotated based on driving of the first driving motor, and wherein the fourth rotating member is rotated based on driving of the second driving motor.

### CROSS-REFERENCE TO RELATED APPLICATIONS

This application is a continuation of International Application No. PCT/KR2024/006735, filed on May 17, 2024, and claiming priority to Korean Patent Application No. 10-2023-0091991, filed on July 14, 2023, in the Korean Intellectual Property Office, the disclosures of each of which are incorporated by reference herein in their entireties.

### BACKGROUND

### 1. Field

This disclosure relates to an angle adjusting device for a display adjusting a display at various angles.

### 2. Description of Related Art

A display device, as a device displaying a screen, includes a monitor or a television. For the display device, a self-light emitting display panel such as an organic light emitting diode or a micro light emitting diode, and a light receiving and emitting display panel such as a liquid crystal display panel are used. The display device is configured to include a display assembly displaying an image, and a stand supporting the display assembly approximately shaped into a plate, and the like.

### SUMMARY

According to an aspect of the disclosure, there is provided an angle adjusting device for a display, including: a base; a joint disposed between the base and the display, the joint configured to change an angle of the display; a first driving motor providing power to one side of the joint; and a second driving motor providing power to the other side of the joint, wherein the joint includes: a connecting core; and a first rotating member, a second rotating member, a third rotating member and a fourth rotating member rotatably connected to the connecting core respectively in four directions of the connecting core, wherein the first rotating member and the second rotating member are disposed along a first axis, and the third rotating member and the fourth rotating member are disposed along a second axis perpendicular to the first axis, wherein the third rotating member is rotated based on driving of the first driving motor, and wherein the fourth rotating member is rotated based on driving of the second driving motor.

The connecting core may include: a first connecting shaft and a second connecting shaft provided along the first axis; and a third connecting shaft and a fourth connecting shaft provided along the second axis.

The first rotating member may include: a first friction wheel rotatably coupled to the first connecting shaft; and a first gear coaxially coupled to the first friction wheel, wherein the second rotating member may include: a second friction wheel rotatably coupled to the second connecting shaft; and a second gear coaxially coupled to the second friction wheel, wherein the third rotating member may include: a third friction wheel rotatably coupled to the third connecting shaft, and closely contacting the first friction wheel and the second friction wheel in a linkable manner; and a third gear coaxially coupled with the third friction wheel, and gear-coupled to the first gear and the second gear, and wherein the fourth rotating member may include: a fourth friction wheel rotatably coupled to the fourth connecting shaft, the fourth friction wheel closely contacting the first friction wheel and the second friction wheel in a linkable manner; and a fourth gear coaxially coupled with the fourth friction wheel, and gear-coupled to the first gear and the second gear.

The first friction wheel may be fixed to a rear surface of the display.

The first gear, the second gear, the third gear and the fourth gear may be respectively a bevel gear.

The joint further may include a stopper coupled to the connecting core, wherein the angle adjusting device for a display further may include a first angle limiting member provided at the base and interfering with the stopper, and wherein the joint may be tilted around the first axis within an angle range in which the stopper is interfered with by the first angle limiting member.

The first angle limiting member may include a groove into which the stopper is rotatably inserted around the first axis.

The angle adjusting device for a display may further include: a first damper disposed between the first driving motor and the third friction wheel, and transferring a driving force of the first driving motor to the third friction wheel; and a second damper disposed between the second driving motor and the fourth friction wheel, and transferring a driving force of the second driving motor to the fourth friction wheel.

The first damper and the second damper may be respectively a rotary damper.

The angle adjusting device for a display may further include: a second angle limiting member disposed between the first damper and the second damper, wherein the joint may be tilted around the second axis within an angle range in which the first friction wheel and the second friction wheel may be interfered with by the second angle limiting member.

According to an aspect of the disclosure, there is provided an angle adjusting device for a display, including: a base; a joint connecting a rear surface of the display and the base, rotating the display around a first axis within a first tilting angle range, and rotating the display around a second axis perpendicularly crossing the first axis within a second tilting angle range; and a first driving motor and a second driving motor providing power to the joint such that the joint is rotated respectively around the first axis and the second axis.

The first driving motor and the second driving motor may be rotary-driven in a different direction to rotate the joint around the first axis, and wherein the first driving motor and the second driving motor may be both rotary-driven in an identical direction to rotate the joint around the second axis.

The joint may include: a first friction wheel and a second friction wheel disposed symmetrically along the first axis; a third friction wheel and a fourth friction wheel disposed symmetrically along the second axis; and a first gear, a second gear, a third gear and a fourth gear coupled respectively and adjacent to front end portions of the first, second, third and fourth friction wheels, each of the first, second, third and fourth friction wheels links with two friction wheels adjacent to each of the first, second, third and fourth friction wheels, among the first, second, third and fourth friction wheels, and each of the first, second, third and fourth gears links with two gears adjacent to each of the first, second, third and fourth gears, among of the first, second, third and fourth gears.

The angle adjusting device may include: a first angle limiting member limiting the first tilting angle range of the joint tilted around the first axis; and a second angle limiting member limiting the second tilting angle range of the joint tilted around the second axis.

The angle adjusting device may include: a first rotary damper disposed between the first driving motor and the third friction wheel; and a second rotary damper disposed between the second driving motor and the fourth friction wheel.

### BRIEF DESCRIPTION OF THE DRAWINGS

The above and other aspects and/or features of embodiments of the disclosure will become more apparent from the following detailed description taken in conjunction with the accompanying drawings, in which:

FIG. 1 is a view illustrating an example of an angle adjusting device for a display installed in a mobile robot according to one or more embodiments;

FIG. 2 is an exploded view illustrating an example of an angle adjusting device for a display connected to a display according to one or more embodiments;

FIGS. 3 and 4 are views illustrating an angle adjusting device for a display according to one or more embodiments;

FIG. 5 is an exploded view illustrating a joint unit of an angle adjusting device for a display according to one or more embodiments;

FIG. 6 is a plan view illustrating a joint unit of an angle adjusting device for a display according to one or more embodiments;

FIG. 7 is a side view illustrating a joint unit of an angle adjusting device for a display according to one or more embodiments;

FIG. 8 is a cross-sectional view along line A-A’ illustrated in FIG. 7;

FIG. 9 is a block diagram illustrating an angle adjusting device for a display according to one or more embodiments;

FIGS. 10 and 11 are views provided to explain a roll motion of a display based on driving of a joint unit of an angle adjusting device for a display according to one or more embodiments; and

FIGS. 12 and 13 are views provided to explain a pitch (roll) motion of a display based on driving of a joint unit of an angle adjusting device for a display according to one or more embodiments.

### DETAILED DESCRIPTION

The embodiments described in the present disclosure and the configurations illustrated in the drawings are provided only as one or more examples, and at a point in time when the disclosure is filed, there may be various modifications replaceable with the embodiments and the drawings in the disclosure.

In the disclosure, like reference numerals or symbols in each of the drawings substantially indicate like components or elements performing like functions.

Terms used herein are used to describe the embodiments, and are not intended to limit and/or restrict the subject matter of the disclosure. Unless explicitly stated otherwise, singular forms may include plural forms as well. In the disclosure, terms such as “include,” or “have” and the like are used to indicate the presence of stated features, numbers, steps, operations, elements, components or a combination thereof, and do not imply exclusion of the presence or addition of one or more different features, numbers, steps, operations, elements, components or a combination thereof.

In the disclosure, terms including ordinal numbers such as “1^{st},” “2^{nd},” and the like may be used to describe various elements, but not to limit the elements. The terms used herein are merely used to differentiate one element from another. For example, a first element may be referred to as a second element, and similarly, a second element may be referred to as a first element without departing from the scope of the right to the subject matter of the disclosure. The term “and/or” includes a combination of a plurality of stated relevant elements or any one of the plurality of stated relevant elements.

In the disclosure, terms such as “front end,” “rear end,” “upper portion,” “lower portion,” “front surface,” “rear surface,” “upper surface,” “lower surface,” “upper end,” “lower end,” “one end,” “the other end,” “left side,” “right side,” and the like are defined with respect to the drawings, and are not intended to limit the shape and position of each of the elements.

Hereafter, an angle adjusting device for a display according to one or more embodiments is described in detail with reference to the accompanying drawings.

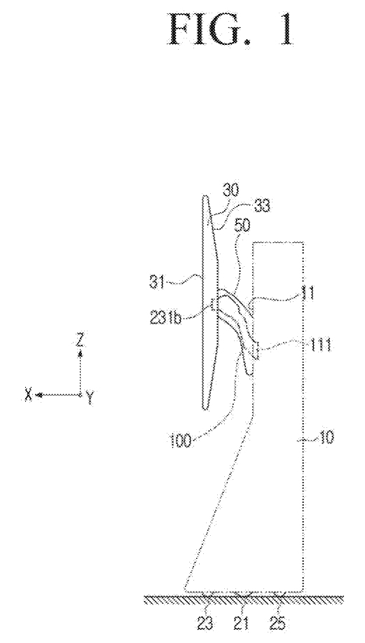

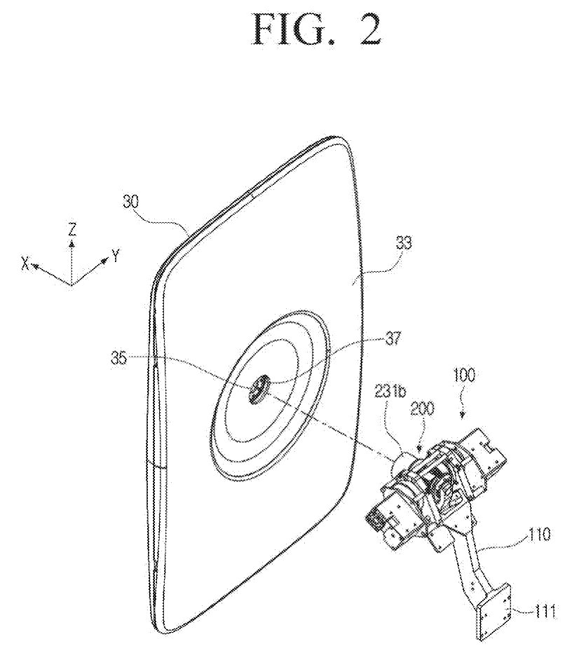

FIG. 1 is a view illustrating an example of an angle adjusting device for a display installed in a mobile robot according to one or more embodiments. FIG. 2 is an exploded view illustrating an example of an angle adjusting device for a display connected to a display according to one or more embodiments.

Referring to FIG. 1, an angle adjusting device for a display 100 may cause a display 30 to perform a pitch motion, a roll motion and a combination of the pitch and roll motions, such that the display 30 is adjustable at various angles. The angle adjusting device for a display 100 may adjust the display 30 at various angles based on a compact size and small power, to provide convenience to the user.

The angle adjusting device for a display 100 may rotate (pitch) the display 30 around the Y axis of FIG. 1 to adjust the angle of the display 30. The angle adjusting device for a display 100 may rotate (roll) the display 30 around the X axis of FIG. 1 to adjust the angle of the display 30. The angle adjusting device for a display 100 may rotate (combine a pitch and a roll) the display 30 around the Y axis and X axis of FIG. 1 at the same time to adjust the angle of the display 30.

The angle adjusting device for a display 100 may connect the display 30 to a mobile robot 10. The mobile robot 10 may be provided, in the lower portion thereof, with a plurality of driving wheels 21, and a plurality of idle wheels 23, 25 disposed respectively at the front and the rear of the plurality of driving wheels 21.

Vibrations generated at a time when the mobile robot 10 travels may be transferred to the angle adjusting device for a display 100. The angle adjusting device for a display 100 may include a vibration absorbing structure capable of absorbing the vibrations transferred from the mobile robot 10. Accordingly, the angle adjusting device for a display 100 may absorb the vibrations transferred to the angle adjusting device for a display 100 and mitigate or minimize a shake of the display 30 at a time when the mobile robot 10 travels. Hereafter, the vibration absorbing structure is described in detail.

The display 30 may be connected to the mobile robot 10 by the angle adjusting device for a display 100. The angle adjusting device for a display 100 may be disposed between a rear surface 33 of the display 30 and a front surface 11 of the mobile robot 10. In this case, the angle adjusting device for a display 100 may be wrapped by a cover 50. The cover 50 may prevent the exposure of the angle adjusting device for a display 100 such that the angle adjusting device for a display 100 is protected from an external shock and the contamination of the angle adjusting device for a display 100, caused by a foreign substance such as dust and the like, is mitigated or minimized.

A mounting unit 111 of the angle adjusting device for a display 100 may be connected to the front surface 11 of the display 30. Accordingly, a base 110 of the angle adjusting device for a display 100 may be fixed to the mobile robot 10.

In the disclosure, the angle adjusting device for a display 100 mounted on the mobile robot 10 is described, for example, but not limited thereto. For example, the angle adjusting device for a display 100 may be mounted on a fixed structure such as a wall or furniture such as a desk that is not frequently moved. In this case, the angle adjusting device for a display 100 may connect the display 30 to a wall or a desk.

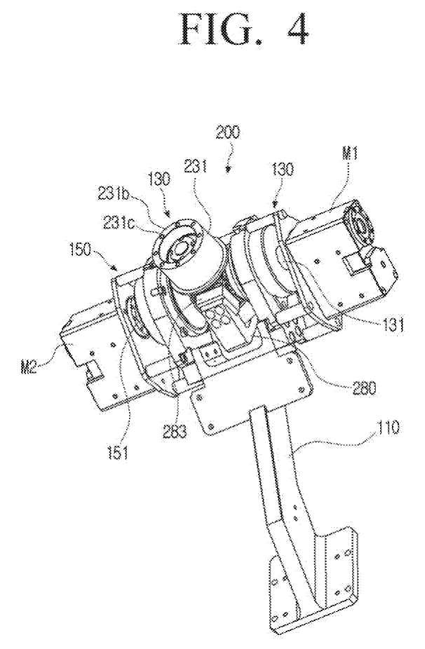

Referring to FIG. 2, a rear end 231b of a first friction wheel 231 of the angle adjusting device for a display 100 may be inserted into a coupling hole 35 formed on the rear surface 33 of the display 30. A connecting unit 231b of the angle adjusting device for a display 100 may be firmly connected with the display 30 by a plurality of fasteners (hereafter, referred to as a “screw”). In this case, the plurality of screws may be fastened to a plurality of fastening holes 231c (see FIG. 4) provided at the rear end 231b of the first friction wheel 231 of the angle adjusting device for a display 100 through a plurality of penetration holes 37 provided at the display 30. Accordingly, the display 30 may be rotated together with the first friction wheel 231 of the angle adjusting device for a display 100.

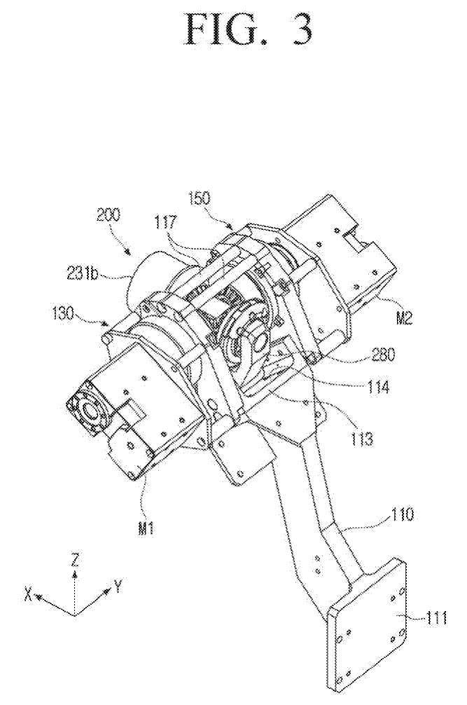

Hereafter, a configuration of the angle adjusting device for a display according to one or more embodiments is described in detail with reference to the drawings. FIGS. 3 and 4 are views illustrating an angle adjusting device for a display according to one or more embodiments.

Referring to FIGS. 3 and 4, the angle adjusting device for a display 100 may include a base 110 connected to the mobile robot 10, a joint unit 200 capable of adjusting an angle of the display 30 (see FIG. 2), a first driving motor M1 provided on the left side of the joint unit 200, and a second driving motor M2 provided on the right side of the joint unit 200. The first driving motor M1 and the second driving motor M2 may be a stepping motor or a servo motor capable of being rotatably driven clockwise and counterclockwise.

The base 110 may be provided, at the rear end thereof, with the mounting unit 111 that can be connected to the mobile robot 10 by a plurality of screws. The mounting unit 111 of the base 110 may be separably fastened to the front surface of the mobile robot 10 by the plurality of screws.

The base 110 may be provided, at the front end thereof, with a first angle limiting member 113 that can limit an angle at which the joint unit 200 is rotated around the X axis. Since the angle at which the joint unit 200 is rotated around the X axis is limited by the first angle limiting member 113, a tilting angle range of the display 30 may be limited at a time of roll movement. For example, the tilting angle range may be ±180 degrees at a time of roll movement of the display 30.

The first angle limiting member 113 may be provided with a groove 114 in which a stopper 280 of the joint unit 200 can be rotated in a predetermined angle range. The groove 114 of the first angle limiting member 113 may be approximately shaped into “U”. The tilting angle range of the display 30 at a time of roll movement may be set based on a width (a length along the Y-axis direction) of the groove 114 of the first angle limiting member 113. The groove 114 of the first angle limiting member 113.

A first damper 130 may be connected to the left side of the first angle limiting member 113, and a second damper 150 may be connected to the right side of the first angle limiting angle 113. The first damper 130 and the second damper 150 may be provided symmetrically with respect to the joint unit 200. The first damper 130 and the second damper 150 may be rotary dampers.

The first driving motor M1 may be connected to one side of the first damper 130. The first damper 130 may transfer the power of the first driving motor M1 to the joint unit 200. In this case, the first damper 130 may mitigate or reduce vibrations and a backlash caused by driving of the first driving motor M1 to provide the power of the first driving motor M1 reliably to the joint unit 200.

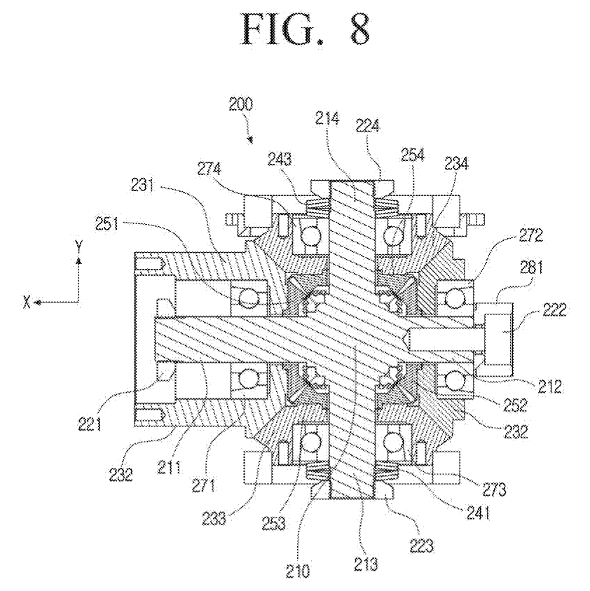

The first damper 130 may be provided with a first shaft member 131 connected to a driving shaft of the first driving motor M1. The first shaft member 131 may be disposed coaxially with a third connecting shaft 213 (see FIG. 8) of a connecting core 210 of the joint unit 200.

The first shaft member 131 may be connected with a third friction wheel 233 of the joint unit 200. The first shaft member 131 may transfer the power of the first driving motor M1 to the third friction wheel 233. In this case, the third friction wheel 233 may be rotated together with the first shaft member 131 clockwise and counterclockwise.

The second driving motor M2 may be connected to one side of the second damper 150. The second damper 150 may transfer the power of the second driving motor M2 to the joint unit 200. In this case, the second damper 150 may mitigate or reduce vibrations and a backlash caused by driving of the second driving motor M2 to provide the power of the second driving motor M2 reliably to the joint unit 200.

The second damper 150 may be provided with a second shaft member 151 connected to a driving shaft of the second driving motor M2. The second shaft member 151 may be disposed coaxially with a fourth connecting shaft 214 (see FIG. 8) of the connecting core 210 of the joint unit 200. Accordingly, the first and second shaft members 141, 151 and the third and fourth connecting shafts 213, 214 of the connecting core 210 of the joint unit 200 may all be provided on the same coaxial axis (e.g., a Y axis).

The second shaft member 151 may be connected with a fourth friction wheel 234 of the joint unit 200. The second shaft member 151 may transfer the power of the second driving motor M2 to the fourth friction wheel 234. In this case, the fourth friction wheel 234 may be rotated together with the second shaft member 151 clockwise and counterclockwise.

The joint unit 200 may receive the power of the first driving motor M1 reliably through the first damper 130, and may receive the power of the second driving motor M2 reliably through the second damper 150.

The lower end of the first damper 130 and the lower end of the second damper 150 may respectively be separably fixed to the left side and the right side of the first angle limiting member 113 by a plurality of screws. The upper end of the first damper 130 and the upper end of the second damper 150 may be connected to each other by a second angle limiting member 117. In this case, the second angle limiting member 117 may be disposed between the first damper 130 and the second damper 150, and may be parallel with the first shaft member 131 of the first damper 130 and the second shaft member 151 of the second damper 150.

The second angle limiting member 117 may limit a tilting angle range in which the joint unit 200 is rotated around the Y axis. For example, in the case where the joint unit 200 is rotated around the Y axis, the first friction wheel 231 and a second friction wheel 231 included in the joint unit 200 may be interfered with by the second angle limiting member 117 when the joint unit 200 is placed at a predetermined angle. Accordingly, the tilting angle range of the display 30 may be limited at a time of pitch movement. For example, the tilting angle range may be ±25 degrees at a time of pitch movement of the display 30, but not limited thereto.

The second angle limiting member 117 may include a plurality of rods. For example, the second angle limiting member 117 may include two rods that are spaced from each other as shown in FIG. 3. As a gap between the two rods is widened, the tiling angle range may be narrowed at a time of pitch movement of the display 30.

The second angle limiting member 117 may not be limited to a second angle limiting member comprised of two rods, and may also be implemented as one plate. In this case, the width (a length along the X-axis direction) of the plate may be a length corresponding to a distance between the two rods.

The joint unit 200 may receive power from the first driving motor M1 and the second driving motor M2 to tilt the display 30 based on a pitch, a roll and a combination of a pitch and a roll. For example, the joint unit 200 may receive a rotational force of the same direction from the first driving motor M1 and the second driving motor M2 to tilt the display 30 around the Y axis at a predetermined angle. The joint unit 200 may receive a rotational force of directions opposite to each other from the first driving motor M1 and the second driving motor M2 to tilt the display 30 around the X axis at a predetermined angle.

The joint unit 200 may adopt a connection structure among the plurality of friction wheels and a connection structure among a plurality of gears together to tilt the display 30 with a small torque, may have a compact size, and may implement a rigid structure that can prevent a slip among the friction wheels and can resist against an external force at a time of driving of the joint unit 200.

Hereafter, the structure of the joint unit 200 of the angle adjusting device 100 for a display according to one or more embodiments is described in detail with reference to the drawings.

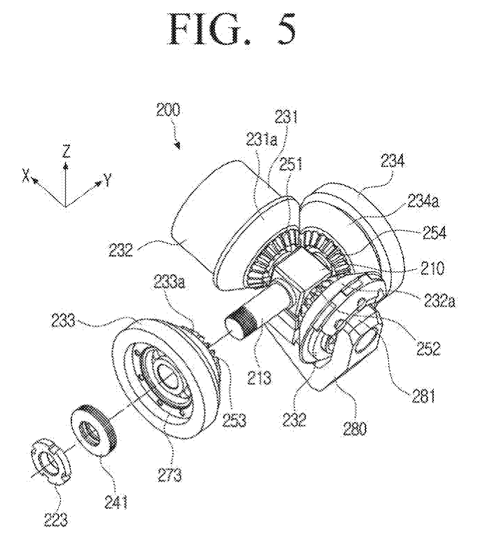

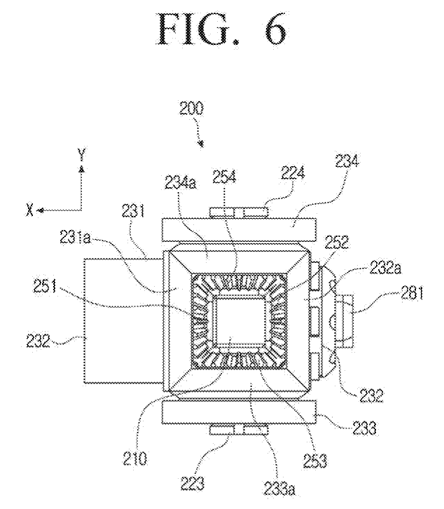

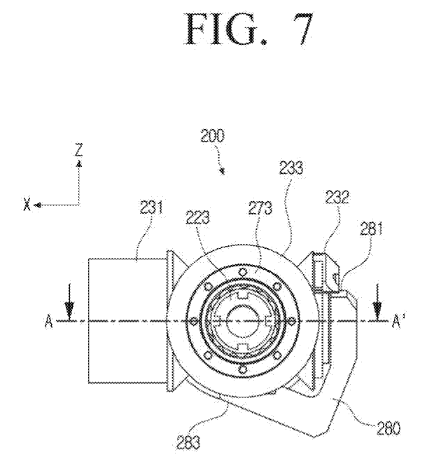

FIG. 5 is an exploded view illustrating a joint unit of an angle adjusting device for a display according to one or more embodiments. FIG. 6 is a plan view illustrating a joint unit of an angle adjusting device for a display according to one or more embodiments. FIG. 7 is a side view illustrating a joint unit of an angle adjusting device for a display according to one or more embodiments. FIG. 8 is a cross-sectional view along line A-A’ illustrated in FIG. 7.

Referring to FIGS. 5 and 6, the joint unit 200 may include a connecting core 210, first, second, third and fourth friction wheels 231, 232, 233, 234, first, second, third and fourth gears 251, 252, 253, 254, and a stopper 280.

The connecting core 210 may include a first connecting shaft 211 to which the first friction wheel 231 is coupled, a second connecting shaft 212 to which the second friction wheel 232 is coupled, a third connecting shaft 213 to which the third friction wheel 233 is coupled, and a fourth connecting shaft 214 to which the fourth friction wheel 234 is coupled. The first connecting shaft 211 and the second connecting shaft 212 may be disposed coaxially (e.g., the X axis). The third connecting shaft 213 and the fourth connecting shaft 214 may be disposed coaxially (e.g., the Y axis).

Part of the first, second, third and fourth friction wheels 231, 232, 233, 234 connected to the connecting core 210 may be disposed in a front-rear direction (the X-axis direction), and the remainders may be disposed in a left-right direction (the Y-axis direction). For example, the first friction wheel 231 and the second friction wheel 232 may be disposed to face each other with a gap therebetween in the front-rear direction (the X-axis direction). The third friction wheel 233 and the fourth friction wheel 234 may be disposed to face each other with a gap therebetween in the left-right direction (the Y-axis direction).

As described above, the first, second, third and fourth friction wheels 231, 232, 233, 234 may be disposed in four directions (front, rear, left and right directions). The first, second, third and fourth friction wheels 231, 232, 233, 234 may have the same diameter. In this case, an inclining surface 231a of the first friction wheel 231 may contact an inclining surface 233a of the third friction wheel 233 and an inclining surface 234a of the fourth friction wheel 234. An inclining surface 232a of the second friction wheel 232 may contact the inclining surface 233a of the third friction wheel 233 and the inclining surface 234a of the fourth friction wheel 234. As for the first, second, third and fourth friction wheels 231, 232, 233, 234, a frictional force may act among the inclining surfaces 231a, 232a, 233a, 234a that contact one another.

Referring to FIG. 8, the first friction wheel 231 may be coupled to the first connecting shaft 211 by a first nut 221 fastened to the first connecting shaft 211 and may not escape from the first connecting shaft 211. The first friction wheel 231 may be provided with a first ball bearing 271 thereinside. The first friction wheel 231 may be rotatably coupled to the first connecting shaft 211 by the first ball bearing 271. The first gear 251 may be coupled to the front end of the first friction wheel 231. The first gear 251 may be rotated together with the first friction wheel 231 in the same direction.

The second friction wheel 232 may be coupled to the second connecting shaft 212 by one end portion 281 of the stopper 280 and may not escape from the second connecting shaft 212. The one end portion 281 of the stopper 280 may be fastened to the second connecting shaft 212 by a screw 222. The second friction wheel 232 may be provided with a second ball bearing 272 thereinside. The second friction wheel 232 may be rotatably coupled to the second connecting shaft 212 by the second ball bearing 272. The second gear 252 may be coupled to the front end of the second friction wheel 232. The second gear 252 may be rotated together with the second friction wheel 232 in the same direction.

The third friction wheel 233 may be coupled to the third connecting shaft 213 by a second nut 223 fastened to the third connecting shaft 213 and may not escape from the third connecting shaft 213. In this case, the second nut 223 may be fastened to the third connecting shaft 213 in the state where the second nut 223 is coupled to the third connecting shaft 213 by a plurality of first spring washers 241. In this case, the plurality of first spring washers 241 may prevent the loosening of the second nut 223 from the third connecting shaft 213, caused by vibrations that are generated at a time of driving of the first driving motor M1.

The third friction wheel 233 may be provided with a third ball bearing 273 thereinside. The third friction wheel 233 may be rotatably coupled to the third connecting shaft 213 by the third ball bearing 273. The third gear 253 may be coupled to the front end of the third friction wheel 233. The third gear 253 may be rotated together with the third friction wheel 233 in the same direction.

The fourth friction wheel 234 may be coupled to the fourth connecting shaft 214 by a third nut 224 fasted to the fourth connecting shaft 214 and may not escape from the fourth connecting shaft 214. In this case, the third nut 224 may be fastened to the fourth connecting shaft 214 in the state where the third nut 224 is coupled to the fourth connecting shaft 214 by a plurality of second spring washers 243. The plurality of second spring washers 243 may prevent the loosening of the third nut 224 from the fourth connecting shaft 214, caused by vibrations that are generated at a time of driving of the second driving motor M2.

The fourth friction wheel 234 may be provided with a fourth ball bearing 274 thereinside. The fourth friction wheel 234 may be rotatably coupled to the fourth connecting shaft 214 by the fourth ball bearing 274. The fourth gear 254 may be coupled to the front end of the fourth friction wheel 234. The fourth gear 254 may be rotated together with the fourth friction wheel 234 in the same direction.

The first, second, third and fourth gears 251, 252, 253, 254 may be bevel gears. The first gear 251 and the second gear 252 may be disposed to face each other with a gap therebetween. The third gear 253 and the fourth gear 254 may be disposed to face each other with a gap therebetween. In this case, the first gear 251 may be gear-connected to the third gear 253 and the fourth gear 254. The second gear 252 may be gear-connected to the third gear 253 and the fourth gear 254.

Referring to FIG. 7, the stopper 280 may be approximately shaped into “L” in the way that the stopper 280 is bent between one end portion 281 thereof and the other end portion 283 thereof. The one end portion 281 of the stopper 280 may be fastened to the second connecting shaft 212 by the screw 222, as described above. The other end portion 283 of the stopper 280 may be fastened to the lower surface of the connecting core 210 by a plurality of screws (see FIG. 4). Accordingly, the stopper 280 may be coupled with the connecting core 210 and may be rotated around the X axis and rotated around the Y axis together with the connecting core 210.

The stopper 280 may be disposed in the groove 114 of the first angle limiting member 113. The stopper 280 may be held by both lateral surfaces of the groove 14 of the first angle limiting member 113 at a time when the stopper 280 is rotated around the Y axis together with the connecting core 210, such that the rotation of the stopper 280 is limited. Accordingly, the tilting angle range may be set by the stopper 280 and the first angle limiting member 113 at a time of roll motion of the display 30.

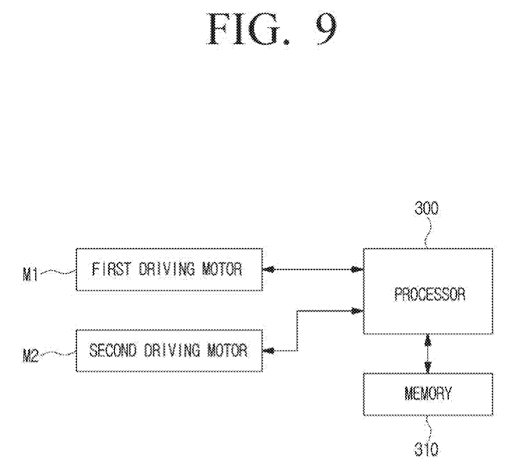

FIG. 9 is a block diagram illustrating an angle adjusting device for a display according to one or more embodiments.

Referring to FIG. 9, the angle adjusting device for a display 100 according to one or more embodiments may further include a processor 300 for controlling the driving of the first driving motor M1 and the second driving motor M2, and memory 310. The processor 300 and the memory 310 may be provided at a predetermined position of the base 110. Additionally, the processor 300 and the memory 310 may be provided at an object in which the angle adjusting device for a display 100 is installed, e.g., a mobile robot 10.

The processor 300 may be comprised of one processor or a plurality of processors. The one processor or the plurality of processors may include at least one of a central processing unit (CPU), a graphics processing unit (GPU), and a neural processing unit (NPU), but not be limited thereto. The CPU, as a generic-purpose processor capable of performing an AI computation as well as a normal computation, may efficiently execute a complex program through a multi-level cache structure. The CPU is advantageous in a series processing method enabling an organic connection between previous calculation results and following calculation results based on a consecutive calculation. The generic-purpose processor is not limited to the above-described examples, unless explicitly indicated as the above-described CPU.

The memory 310 is an element for storing various types of programs and data required for a pitch motion, a roll motion and a combination of the pitch and roll motions 30 of the display 30. The memory 310 may include volatile memory or non-volatile memory. The program may be stored as software in the memory 310, and for example, may include an operating system, middleware or an application.

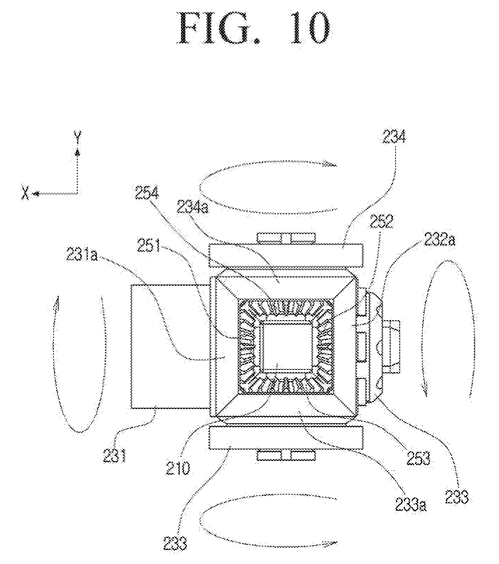

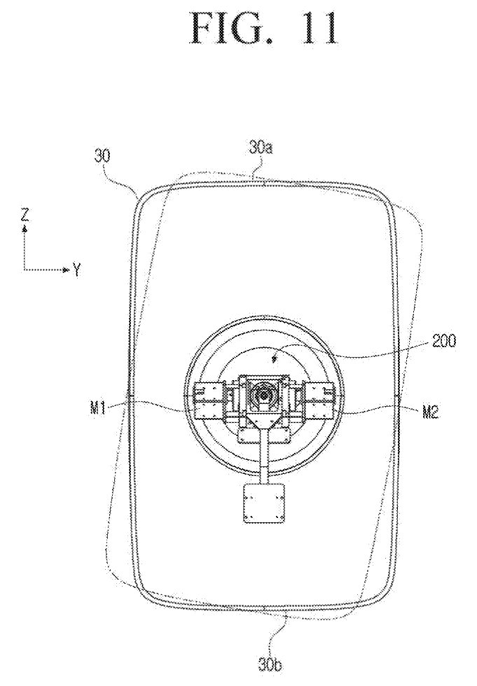

FIGS. 10 and 11 are views provided to explain a roll motion of a display based on driving of a joint unit of an angle adjusting device for a display according to one or more embodiments.

Referring to FIG. 10, for a roll motion of the display 30, the processor 300 may control the driving of the first driving motor M1 such that the first driving motor M1 is rotated in a first direction, and control the driving of the second driving motor M2 such that the second driving motor M2 is rotated in a second direction opposite to the first direction. The third friction wheel 233 and the third gear 253 may be rotated around the Y axis in the first direction, and the fourth friction wheel 234 and the fourth gear 253 may be rotated around the Y axis in the second direction. Accordingly, the first gear 251 may be rotated around the X axis in the first direction in link with rotation of the third gear 253 and the fourth gear 254, and the second gear 252 may be rotated around the X axis in the second direction in link with rotation of the third gear 253 and the fourth gear 254.

In this case, the inclining surfaces 231a, 232a, 233a, 234a of the first, second, third and fourth friction wheels 231, 232, 233, 234 may contact adjacent inclining surfaces thereof in the state where an inclining surface 231a, 232a, 233a, 234a and adjacent inclining surfaces are pressed against one other. Accordingly, at a time when the first, second, third and fourth gears 251, 252, 253, 254 link with each other and are rotated, the first, second, third and fourth gears 251, 252, 253, 254 may be rotated reliably without causing a slip.

Referring to FIG. 11, the display 30 connected with the first friction wheel 231 may perform a roll movement in the same direction (a clockwise direction) as the direction in which the first friction wheel 231 is rotated and may be tilted by an angle corresponding to the angle at which the first friction wheel 231 is rotated. In this case, an upper end 30a of the display 30 may be rotated to the right at a predetermined angle, and a lower end 30b of the display 30 may be rotated to the left by an angle the same as the angle at which the upper end 30a of the display 30 is rotated.

On the contrary, the processor 300 may control the driving of the first driving motor M1 such that the first driving motor M1 is rotated in the second direction, and may control the driving of the second driving motor M2 such that the second driving motor M2 is rotated in the first direction. In this case, the third friction wheel 233 and the third gear 253 may be rotated around the Y axis in the second direction, and the fourth friction wheel 234 and the fourth gear 254 may be rotated around the Y axis in the first direction. Accordingly, the first gear 251 may be rotated around the X axis in the second direction in link with rotation of the third gear 253 and the fourth gear 254, and the second gear 252 and the third gear 253 may be rotated around the X axis in the first direction in link with rotation of the third gear 253 and the fourth gear 254.

Accordingly, the display 30 connected with the first friction wheel 231 may perform a roll movement in the same direction (a counterclockwise direction in FIG. 11) as the direction in which the first friction wheel 231 is rotated, and may be tilted by an angle corresponding to the angle at which the first friction wheel 231 is rotated.

The angle adjusting device for a display 100 according to one or more embodiments may cause the display 30 to roll and rotate by a desired angle within the tilting angle range (e.g., ±180 degrees). For example, the angle adjusting device for a display 100 may adjust the display 30 such that the display 30 staying vertical is rotated at 90 degrees and placed horizontally. Additionally, the angle adjusting device for a display 100 may adjust the display 30 by rotating the display 30 staying vertical at 180 degrees such that the upper end 30a of the display 30 and the lower end 30b of the display 30 are placed in the opposite way.

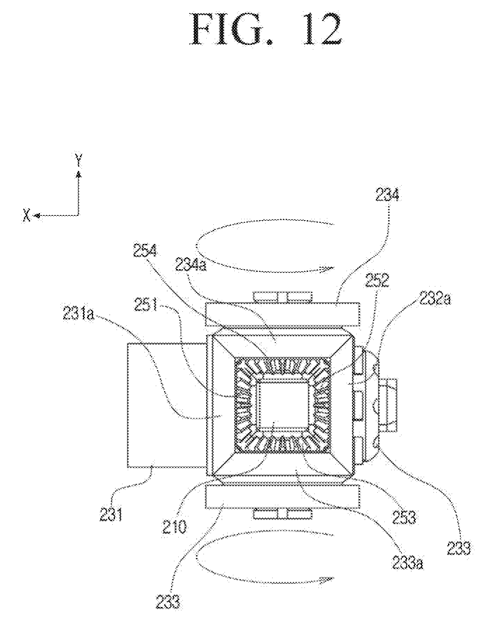

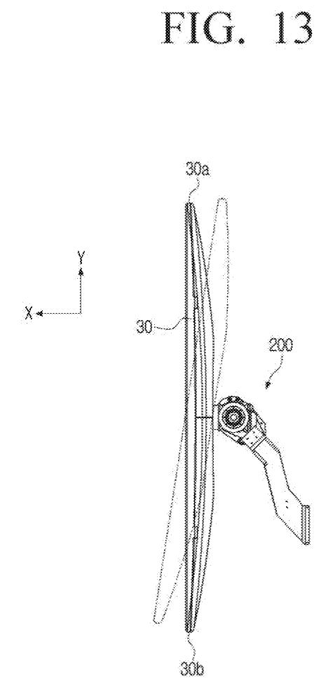

FIGS. 12 and 13 are views provided to explain a pitch (roll) motion of a display based on driving of a joint unit of an angle adjusting device for a display according to one or more embodiments.

Referring to FIG. 12, for a pitch motion of the display 30, the processor 300 may control the driving of the first driving motor M1 and the second driving motor M2 such that the first driving motor M1 and the second driving motor M2 are both rotated in the second direction.

In this case, the third friction wheel 233 and the fourth friction wheel 234 are rotated together in the second direction, but the third gear 253 receiving power generated from the first driving motor M1 through the first damper 130 and the fourth gear 254 receiving power generated from the second driving motor M2 through the second damper 150 are locked by the first gear 251 and the second gear 252. Accordingly, the first, second, third and fourth gears 251, 252, 253, 254 are not rotated among one another. Additionally, the first, second, third and fourth friction wheels 231, 232, 233, 234 are not rotated among one another.

Accordingly, the entire joint unit 200 may be rotated around the Y axis by the driving force of the first driving motor M1 and the second driving motor M2.

Referring to FIG. 13, the display 30 may be rotated together with the joint unit 200 in the same direction as the direction in which the joint unit 200 is rotated. In this case, the upper end 30a of the display 30 may be moved back, and the lower end 30b of the display 30 may be moved forth. As described above, the angle adjusting device for a display 100 may cause the display 30 to pitch and rotate by a desired angle within the tilting angle range (e.g., ±25 degrees). Herein, the tilting angle range based on the pitch movement of the display 30 is not limited to the ±25 degrees.

The processor 300 may control the display 30 such that the display 30 performs a combined movement where a roll and a pitch are combined based on driving of the joint unit 200. For example, the processor 300 may control the first driving motor M1 and the second driving motor M2 such that the first driving motor M1 and the second driving motor M2 are rotary-driven in an opposite direction, thereby tilting the display 30 around the X axis clockwise at 45 degrees (a roll movement of the display 30). Then the processor 300 may control the first driving motor M1 and the second driving motor M2 such that the first driving motor M1 and the second driving motor M2 are rotary-driven in the same direction, thereby tilting the display 30 around the third and fourth connecting shafts 213, 214 of the connecting core 210 at 15 degrees (a pitch movement of the display 30).

The angle adjusting device for a display 100 according to one or more embodiments may not be limitedly mounted in a mobile robot 10 but may be mounted in various types of mobile objects, e.g., a vehicle, a truck, a ship and the like.

According to an embodiment, an angle adjusting device for a display includes: a base; a joint disposed between the base and the display, the joint configured to change an angle of the display; a first driving motor providing power to one side of the joint; and a second driving motor providing power to the other side of the joint, wherein the joint includes: a connecting core; and a first rotating member, a second rotating member, a third rotating member and a fourth rotating member rotatably connected to the connecting core respectively in four directions of the connecting core, wherein the first rotating member and the second rotating member are disposed along a first axis, and the third rotating member and the fourth rotating member are disposed along a second axis perpendicular to the first axis, wherein the third rotating member is rotated based on driving of the first driving motor, and wherein the fourth rotating member is rotated based on driving of the second driving motor.

According to an embodiment, an angle adjusting device for a display includes: a base; a joint connecting a rear surface of the display and the base, rotating the display around a first axis within a first tilting angle range, and rotating the display around a second axis perpendicularly crossing the first axis within a second tilting angle range; and a first driving motor and a second driving motor providing power to the joint such that the joint is rotated respectively around the first axis and the second axis.

While example embodiments of the disclosure are illustrated and described above, embodiments of the disclosure are not limited to the embodiments set forth herein, and certainly, various modifications thereof may be made by those skilled in the art to which the disclosure pertains, without departing from the scope of the disclosure, claimed in the section of claims, and should not be understood as separating from the technical spirit or prospect of the disclosure.

What is claimed is:

1. An angle adjusting device for a display, comprising:
a base;
a joint disposed between the base and the display, the joint configured to change an angle of the display;
a first driving motor providing power to one side of the joint; and
a second driving motor providing power to the other side of the joint,
wherein the joint comprises:
a connecting core; and
a first rotating member, a second rotating member, a third rotating member and a fourth rotating member rotatably connected to the connecting core respectively in four directions of the connecting core,
wherein the first rotating member and the second rotating member are disposed along a first axis, and the third rotating member and the fourth rotating member are disposed along a second axis perpendicular to the first axis,
wherein the third rotating member is rotated based on driving of the first driving motor, and
wherein the fourth rotating member is rotated based on driving of the second driving motor.

2. The angle adjusting device for the display as claimed in claim 1, wherein the connecting core comprises:
a first connecting shaft and a second connecting shaft provided along the first axis; and
a third connecting shaft and a fourth connecting shaft provided along the second axis.

3. The angle adjusting device for the display as claimed in claim 2, wherein the first rotating member comprises:
a first friction wheel rotatably coupled to the first connecting shaft; and
a first gear coaxially coupled to the first friction wheel,
wherein the second rotating member comprises:
a second friction wheel rotatably coupled to the second connecting shaft; and
a second gear coaxially coupled to the second friction wheel,
wherein the third rotating member comprises:
a third friction wheel rotatably coupled to the third connecting shaft, and closely contacting the first friction wheel and the second friction wheel in a linkable manner; and
a third gear coaxially coupled with the third friction wheel, and gear-coupled to the first gear and the second gear, and
wherein the fourth rotating member comprises:
a fourth friction wheel rotatably coupled to the fourth connecting shaft, the fourth friction wheel closely contacting the first friction wheel and the second friction wheel in a linkable manner; and
a fourth gear coaxially coupled with the fourth friction wheel, and gear-coupled to the first gear and the second gear.

4. The angle adjusting device for the display as claimed in claim 3, wherein the first friction wheel is fixed to a rear surface of the display.

5. The angle adjusting device for the display as claimed in claim 3, wherein the first gear, the second gear, the third gear and the fourth gear are respectively a bevel gear.

6. The angle adjusting device for the display as claimed in claim 2, wherein the joint further comprises a stopper coupled to the connecting core,
wherein the angle adjusting device for the display further comprises a first angle limiting member provided at the base and interfering with the stopper, and
wherein the joint is tilted around the first axis within an angle range in which the stopper is interfered with by the first angle limiting member.

7. The angle adjusting device for the display as claimed in claim 6, wherein the first angle limiting member comprises a groove into which the stopper is rotatably inserted around the first axis.

8. The angle adjusting device for the display as claimed in claim 3, further comprising:
a first damper disposed between the first driving motor and the third friction wheel, and transferring a driving force of the first driving motor to the third friction wheel; and
a second damper disposed between the second driving motor and the fourth friction wheel, and transferring a driving force of the second driving motor to the fourth friction wheel.

9. The angle adjusting device for the display as claimed in claim 8, wherein the first damper and the second damper are respectively a rotary damper.

10. The angle adjusting device for the display as claimed in claim 8, further comprising:
a second angle limiting member disposed between the first damper and the second damper,
wherein the joint is tilted around the second axis within an angle range in which the first friction wheel and the second friction wheel are interfered with by the second angle limiting member.

11. An angle adjusting device for a display, comprising:
a base;
a joint connecting a rear surface of the display and the base, rotating the display around a first axis within a first tilting angle range, and rotating the display around a second axis perpendicularly crossing the first axis within a second tilting angle range; and
a first driving motor and a second driving motor providing power to the joint such that the joint is rotated respectively around the first axis and the second axis.

12. The angle adjusting device for the display as claimed in claim 11, wherein the first driving motor and the second driving motor are rotary-driven in a different direction to rotate the joint around the first axis, and
wherein the first driving motor and the second driving motor are both rotary-driven in an identical direction to rotate the joint around the second axis.

13. The angle adjusting device for the display as claimed in claim 12, wherein the joint comprises:
a first friction wheel and a second friction wheel disposed symmetrically along the first axis;
a third friction wheel and a fourth friction wheel disposed symmetrically along the second axis; and
a first gear, a second gear, a third gear and a fourth gear coupled respectively and adjacent to front end portions of the first, second, third and fourth friction wheels,
each of the first, second, third and fourth friction wheels links with two friction wheels adjacent to each of the first, second, third and fourth friction wheels, among the first, second, third and fourth friction wheels, and
each of the first, second, third and fourth gears links with two gears adjacent to each of the first, second, third and fourth gears, among of the first, second, third and fourth gears.

14. The angle adjusting device for the display as claimed in claim 12, further comprising:
a first angle limiting member limiting the first tilting angle range of the joint tilted around the first axis; and
a second angle limiting member limiting the second tilting angle range of the joint tilted around the second axis.

15. The angle adjusting device for the display as claimed in claim 13, further comprising:
a first rotary damper disposed between the first driving motor and the third friction wheel; and
a second rotary damper disposed between the second driving motor and the fourth friction wheel.
